(19) United States
(12) Patent Application Publication
(10) Pub. No.: US 2016/0079217 A1
(43) Pub. Date: Mar. 17, 2016

(54) SEMICONDUCTOR LIGHT EMITTING DEVICE AND LEAD FRAME

(71) Applicant: Kabushiki Kaisha Toshiba, Tokyo (JP)

(72) Inventors: Hidenori Egoshi, Nonoichi Ishikawa (JP); Yoshio Noguchi, Komatsu Ishikawa (JP); Kazuhiro Inoue, Komatsu Ishikawa (JP); Takashi Arakawa, Hakusan Ishikawa (JP); Teruo Takeuchi, Kanazawa Ishikawa (JP); Toshihiro Kuroki, Nonoichi Ishikawa (JP); Masahiro Ogushi, Nonoichi Ishikawa (JP)

(21) Appl. No.: 14/838,850

(22) Filed: Aug. 28, 2015

(30) Foreign Application Priority Data
Sep. 12, 2014 (JP) 2014-187089
Feb. 6, 2015 (JP) 2015-022237

(51) Int. Cl. H01L 25/16; H01L 33/62; H01L 33/58; H01L 33/56; H01L 33/50; H01L 33/48

(52) U.S. Cl. CPC H01L 25/167; H01L 33/502; H01L 33/486; H01L 33/58; H01L 33/56; H01L 33/62; H01L 2933/0091

(57) ABSTRACT

According to one embodiment, a semiconductor light emitting device includes a lead frame; a chip mounted on the lead frame, the chip including a substrate and a light emitting element provided on the substrate; a wall section including an inner wall facing to a side portion of the chip, and an outer wall on an opposite side to the inner wall; and a phosphor layer provided on at least the chip. A distance between the side portion of the chip and the inner wall of the wall section is smaller than a thickness of the chip. An angle between an upper surface of the lead frame and the inner wall is smaller than an angle between the upper surface of the lead frame and the outer wall.

### CROSS-REFERENCE TO RELATED APPLICATIONS

This application is based upon and claims the benefit of priority from Japanese Patent Application No. 2014-187089, filed on Sep. 12, 2014, and Japanese Patent Application No. 2015-022237, filed on Feb. 6, 2015; the entire contents of all of which are incorporated herein by reference.

### FIELD

Embodiments described herein relate generally to a semiconductor light emitting device and a lead frame.

### BACKGROUND

In surface-mounted light emitting devices using a silicon substrate, there is concerned light absorption in the silicon substrate although significant reduction of the cost can be anticipated.

### BRIEF DESCRIPTION OF THE DRAWINGS

FIGS. 1A to 1C are schematic views of a semiconductor light emitting device of an embodiment;

FIG. 2 is a schematic cross-sectional view of the semiconductor light emitting device of the embodiment;

FIGS. 3A and 3B are schematic views of a package of the embodiment;

FIGS. 4A and 4B are schematic views of the semiconductor light emitting device of the embodiment;

FIG. 5 is an equivalent circuit diagram of the semiconductor light emitting device of the embodiment;

FIGS. 6A and 6B are schematic views of the semiconductor light emitting device of the embodiment;

FIGS. 7A and 7B are schematic views of the semiconductor light emitting device of the embodiment;

FIGS. 8A to 8C are schematic views of a package of the embodiment;

FIG. 9 is a schematic cross-sectional view of the semiconductor light emitting device of the embodiment;

FIG. 10 is a schematic cross-sectional view of the semiconductor light emitting device of the embodiment;

FIGS. 11A and 11B are schematic cross-sectional views of the semiconductor light emitting device of the embodiment;

FIG. 12 is a schematic side view of a lens of the semiconductor light emitting device of the embodiment;

FIG. 13A is a characteristic diagram of ΔCx of the semiconductor light emitting device of the embodiment, and FIG. 13B is a characteristic diagram of ΔCy of the semiconductor light emitting device of the embodiment; and

FIG. 14 is a schematic top view of the semiconductor light emitting device of the embodiment.

### DETAILED DESCRIPTION

According to one embodiment, a semiconductor light emitting device includes a lead frame; a chip mounted on the lead frame, the chip including a substrate and a light emitting element provided on the substrate; a wall section including an inner wall facing to a side portion of the chip, and an outer wall on an opposite side to the inner wall; and a phosphor layer provided on at least the chip. A distance between the side portion of the chip and the inner wall of the wall section is smaller than a thickness of the chip. An angle between an upper surface of the lead frame and the inner wall is smaller than an angle between the upper surface of the lead frame and the outer wall.

An embodiment of the invention will hereinafter be explained with reference to the accompanying drawings. It should be noted that in the drawings, the same elements are denoted with the same reference symbols.

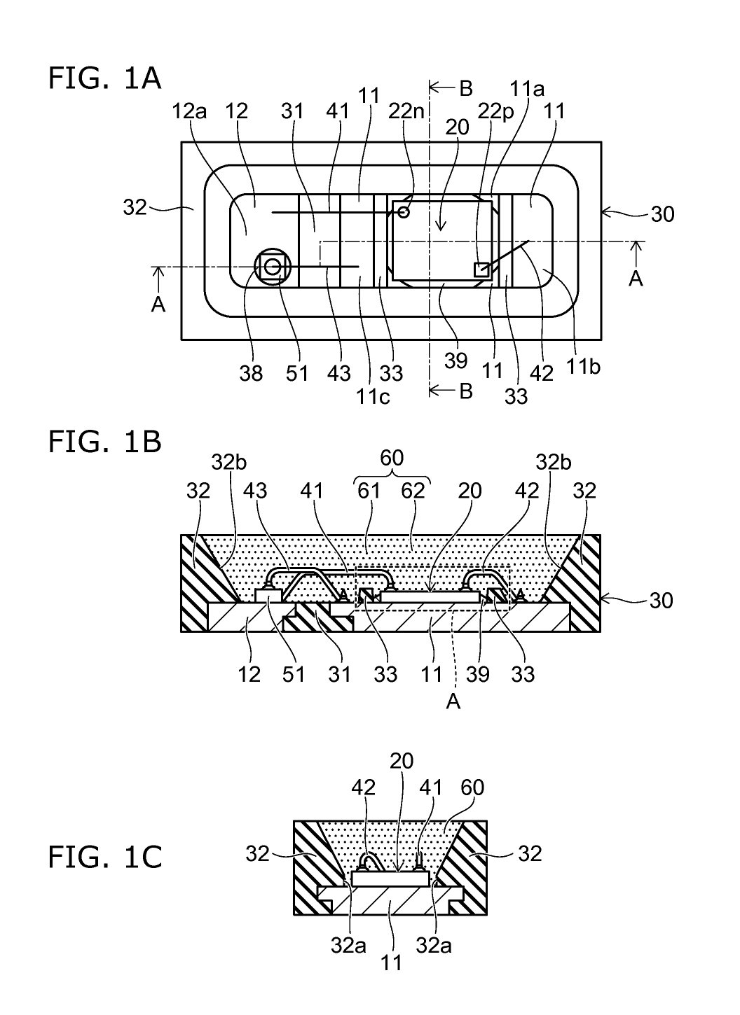

FIG. 1A is a schematic plan view of a semiconductor light emitting device according to the embodiment.

FIG. 1B is an A-A cross-sectional view in FIG. 1A.

FIG. 1C is a B-B cross-sectional view in FIG. 1A.

In FIG. 1A, a phosphor layer 60 shown in FIGS. 1B and 1C is omitted.

The semiconductor light emitting device according to the embodiment includes a chip 20 and a package for holding the chip 20.

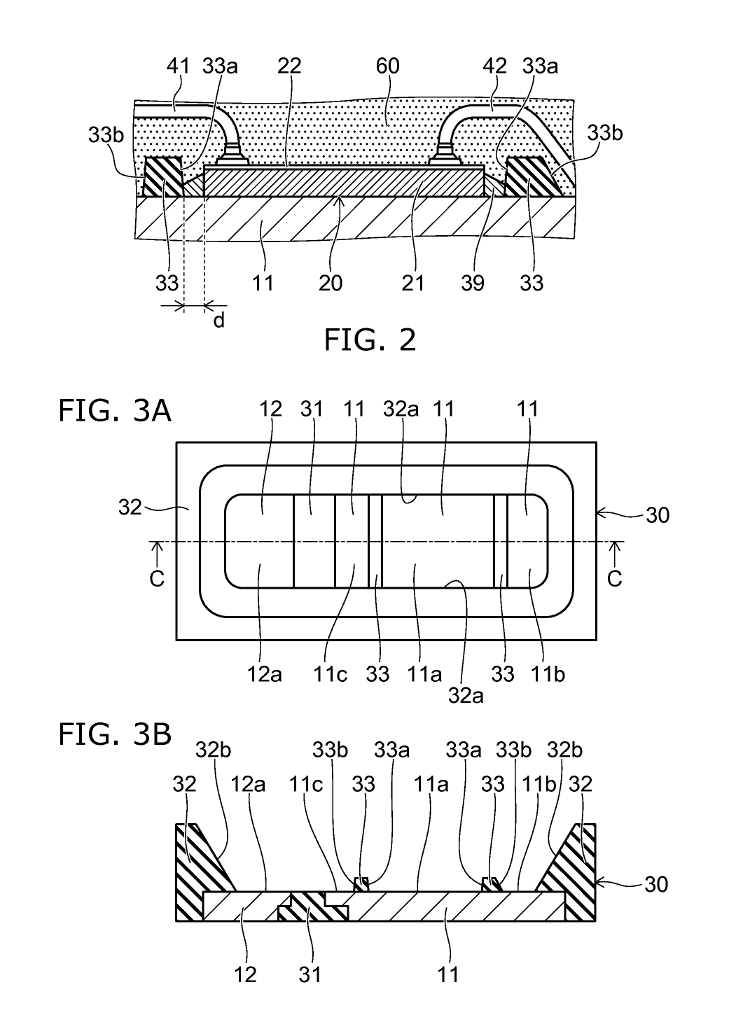

FIG. 2 is an enlarged cross-sectional view of an A part in FIG. 1B.

The chip 20 is a light emitting diode (LED) chip, and has a light emitting element (LED element) 22 and a substrate 21 for supporting the light emitting element 22.

The light emitting element 22 has a semiconductor layer including, for example, gallium nitride. The semiconductor layer has an n-type GaN layer, a p-type GaN layer, and a light emitting layer (an active layer) provided between the n-type GaN layer and the p-type GaN layer. The light emitting layer includes a material for emitting blue light, violet light, bluish-violet light, ultraviolet light, or the like. The emission peak wavelength of the light emitting layer is, for example, in a range of 430 through 470 nm.

Further, the light emitting element 22 has a p-side electrode connected to the p-type GaN layer and an n-side electrode connected to the n-type GaN layer. As shown in FIG. 1A, a p-side pad 22p and an n-side pad 22n are provided on an upper surface of the light emitting element 22. The p-side pad 22p is electrically connected to the p-type GaN layer via the p-side electrode. The n-side pad 22n is electrically connected to the n-type GaN layer via the n-side electrode.

The substrate 21 is, for example, a silicon substrate. The substrate 21 is thicker than the light emitting element 22, and supports the light emitting element 22.

FIG. 3A is a schematic plan view of a package according to the embodiment.

FIG. 3B is a C-C cross-sectional view in FIG. 3A.

The package has a first lead frame 11, a second lead frame 12, and a resin frame 30.

The first lead frame 11 and the second lead frame 12 are each a metal molded object, and contains, for example, copper as a major ingredient. The first lead frame 11 and the second lead frame 12 are separated from each other.

The resin frame 30 has an inter-lead insulating section 31, a reflector 32, and wall sections 33. The inter-lead insulating section 31, the reflector 32, and the wall sections 33 are each formed of, for example, silicone-series white resin.

The inter-lead insulating section 31 is provided between the first lead frame 11 and the second lead frame 12. The upper surface (a boundary portion with the phosphor layer 60) of the first lead frame 11, the upper surface (a boundary portion with the phosphor layer 60) of the second lead frame 12, and an upper surface (a boundary portion with the phosphor layer 60) of the inter-lead insulating section 31 are substantially continuous with each other. The lower surface of the first lead frame 11 not covered with the resin frame 30, the lower surface of the second lead frame 12 not covered with the resin frame 30, and the lower surface of the inter-lead insulating section 31 are substantially continuous with each other.

The reflector 32 is provided to an outer edge portion of the first lead frame 11 and an outer edge portion of the second lead frame 12. An inner wall (a boundary portion with the phosphor layer 60) 32b of the reflector 32 is tilted with respect to the upper surface and the lower surface of the first lead frame 11 and the upper surface and the lower surface of the second lead frame 12. An area above the upper surface of the first lead frame 11 and an area above the upper surface of the second lead frame 12 are continuously surrounded by the inner wall 32b of the reflector 32, and is formed to have an inverted trapezoidal shape in a cross-sectional view shown in FIG. 3B.

As shown in FIG. 3B, the wall sections 33 are provided on the upper surface of the first lead frame 11. The wall sections 33 separate the upper surface of the first lead frame 11 into three areas. The three areas include a first area 11a on which the chip 20 is mounted, and second areas 11b, 11c to which wires are bonded. In other words, the upper surface of the first lead frame 11 is separated by the wall sections 33 into a chip mounting area 11a, and wire bonding areas 11b, 11c.

The wall sections 33 each have an inner wall 33a and an outer wall 33b located on the opposite side. The inner wall 33a faces to the chip mounting area 11a. The outer walls 33b respectively face to the wire bonding areas 11b, 11c.

The chip mounting area 11a is continuously surrounded by the inner walls 33a of the wall sections 33, and the inner wall of the wall section 32a of the reflector 32 shown in FIG. 1C. As shown in FIGS. 1A to 1C, the chip 20 is mounted on the chip mounting area 11a.

A reverse surface of the substrate 21 of the chip 20 is bonded to the upper surface of the first lead frame 11 with die bonding paste 39. The die bonding paste 39 is, for example, silver (Ag) paste.

The heat generated by light emission of the light emitting element 22 is released to a mounting substrate not shown through the substrate 21, the die bonding paste 39, and the first lead frame 11.

The p-side pad 22p of the chip 20 is electrically connected to the first lead frame 11 via a bonding wire 42. One end of the bonding wire 42 is bonded to the p-side pad 22p, and the other end is bonded to the wire bonding area 11b of the first lead frame 11. The bonding wire 42 is bonded to the p-side pad 22p and the wire bonding area 11b so as to straddle over the wall section 33.

The n-side pad 22n of the chip 20 is electrically connected to the second lead frame 12 via a bonding wire 41. One end of the bonding wire 41 is bonded to the n-side pad 22n, and the other end is bonded to the upper surface 12a of the second lead frame 12. The bonding wire 41 is bonded to the n-side pad 22n and the upper surface 12a of the second lead frame 12 so as to straddle over the wall section 33 and the inter-lead insulating section 31.

A zener diode chip (hereinafter simply referred to as a zener diode) 51 is mounted on the upper surface 12a of the second lead frame 12. An anode electrode is formed on the lower surface of the zener diode 51, and a cathode electrode is formed on the upper surface of the zener diode 51.

The anode electrode on the lower surface of the zener diode 51 is connected to the upper surface 12a of the second lead frame 12 via electrically conductive paste (e.g., silver paste) 38.

The cathode electrode on the upper surface of the zener diode 51 is electrically connected to the first lead frame 11 via a bonding wire 43. One end of the bonding wire 43 is bonded to the cathode electrode on the upper surface of the zener diode 51, and the other end is bonded to the wire bonding area 11c of the first lead frame 11.

FIG. 5 is a circuit diagram showing an electrical connection relationship between the LED chip 22 and the zener diode 51.

The LED chip 22 and the zener diode 51 are connected between an anode terminal A and a cathode terminal C in parallel to each other. The first lead frame 11 is connected to the anode terminal A, and the second lead frame 12 is connected to the cathode terminal C.

The LED chip 22 is connected between the anode terminal A and the cathode terminal C in the forward direction. The zener diode 51 is connected between the anode terminal A and the cathode terminal C in the backward direction.

The zener diode 51 functions as an electrostatic discharge (ESD) protection element. When a surge voltage exceeding the maximum rated voltage of the LED chip 22 is applied between the anode terminal A and the cathode terminal C, a surge current flows between the anode terminal A and the cathode terminal C through the zener diode 51.

As shown in FIG. 1B, the phosphor layer 60 is provided in the area on the first and second lead frames 11, 12 surrounded by the reflector 32. The phosphor layer 60 covers the chip 20, the zener diode 51, the wires 41 to 43, the wall sections 33, the upper surface of the first lead frame 11, and the upper surface of the second lead frame 12.

The phosphor layer 60 includes a plurality of phosphor particles 61. The phosphor particles 61 are excited by radiation light of the light emitting element 22, and radiate light different in wavelength from the radiation light. The phosphor particles 61 radiate the light in all directions surrounding the phosphor particles 61.

The plurality of phosphor particles 61 is dispersed in a binder material (binder) 62, and is integrated with the binder material 62. The binder material 62 transmits the radiation light of the light emitting element 22 and the radiation light of the phosphor particles 61. Here, “transmitting” includes not only the fact that the transmittance is 100%, but also the case of absorbing a part of the light.

The phosphor layer 60 has a structure in which the plurality of phosphor particles 61 is dispersed in the binder material 62. For the binder material 62, there can be used transparent resin such as silicone resin. In the specification, “transparent” represents the fact that the object has a transmissive property with respect to the radiation light of the light emitting element and the radiation light of the phosphor particles.

The light radiated from the light emitting element 22 enters the phosphor layer 60, and a part of the light excites the phosphor particles 61, and thus, white light, for example, can be obtained as mixed light of the radiation light of the light emitting element 22 and the radiation light of the phosphor particles 61.

The resin frame 30 including the reflector 32 and the wall sections 33 is formed of white resin having a reflective property with respect to the radiation light of the light emitting element 22 and the radiation light of the phosphor particles 61. The white resin contains, for example, silicone resin as a major ingredient.

The phosphor layer 60 is provided in the area surrounded by the inner wall 32b of the reflector 32. The inner wall 32b of the reflector 32 and the upper surfaces of the lead frames 11, 12 form an obtuse angle. The inner wall 32b of the reflector 32 and the upper surface of the phosphor layer 60 form an acute angle. The inner wall 32b of the reflector 32 is tilted so that the inter-inner wall distance increases in a direction from the lower end to the upper end. Therefore, it is easy for the inner wall 32b to reflect upward the radiation light of the light emitting element 22 and the radiation light of the phosphor particles 61.

Further, a silver (Ag) layer is formed on the upper surface of the first lead frame 11 and the upper surface of the second lead frame 12, using, for example, a plating method. The silver layer has high reflectance with respect to the radiation light of the light emitting element 22 and the radiation light of the phosphor particles 61. Therefore, it is possible to make the radiation light of the phosphor particles 61 and the radiation light of the light emitting element 22, which have proceeded toward the lead frames 11, 12, be reflected by the upper surfaces of the lead frames 11, 12 to proceed upward.

In manufacturing the package, the first lead frame 11 and the second lead frame 12 are disposed in a metal mold. The white resin is cast into the metal mold, and then heated and pressurized to be solidified. Thus, the package, shown in FIGS. 3A and 3B, having the first lead frame 11, the second lead frame 12, and the resin frame 30 integrally bonded to each other, is formed.

Subsequently, the chip 20 is mounted in the chip mounting area 11a, which is surrounded by the wall sections 33 and the wall section 32a (FIG. 1C) of the reflector 32, via the bonding paste 39.

The overall size (the area) of the chip mounting area 11a is slightly larger than the external dimension (the upper surface area or the bottom surface area) of the chip 20, and thus, it is possible to mount the chip 20 in the chip mounting area 11a without interfering with the wall sections 33, 32a. Therefore, gaps are formed between the wall sections 33, 32a and the side surfaces of the chip 20.

Side portions of the chip 20 are facing to the inner walls 33a of the wall sections 33. Side portions (portions facing to the inner walls 33a of the wall sections 33) of the silicon substrate 21 are exposed on the side portions of the chip 20. In this case, the radiation light of the phosphor particles 61 and the radiation light of the light emitting element 22, which has been reflected by the reflector 32 and then returned to the chip side, enter the side portions of the silicon substrate 21, and are thus absorbed by the silicon substrate 21, and therefore there is concerned the deterioration of the light beam to be taken out to the outside of the package.

According to the embodiment, the inner walls of the wall sections 33, 32a continuously surround the periphery of the side portions of the chip 20 while facing to the side portions of the chip 20. The distance (symbol d shown in FIG. 2) between the side portions of the chip 20 and the inner walls of the wall sections 33, 32a is shorter than the thickness of the chip 20.

Since the wall sections 33, 32a are located close to the side portions of the chip 20, the return light proceeding toward the side portions of the chip 20 are blocked (reflected) by the wall sections 33, 32a, and thus, becomes difficult to enter the side portions of the chip 20. As a result, it is possible to suppress the absorption loss of the light in the silicon substrate 21 to improve the light extraction efficiency to the outside of the package.

By preventing the light incidence to the side portions of the chip 20, it is conceivable to make the wall sections 33, 32a have contact with the side portions of the chip 20 to thereby cover the side portions of the chip 20 with the wall sections 33, 32a. However, on the ground of the manufacturing process of mounting the chip 20 after forming the package including the wall sections 33, 32a, it is desirable to form gaps between the wall sections 33, 32a and the side portions of the chip 20.

The smaller the gaps are, the more the light incidence to the side portions of the chip 20 can be reduced. The reduction of the light incidence to the side portions of the chip 20 suppresses the absorption loss of the light in the silicon substrate 21 to improve the light extraction efficiency to the outside of the package. According to the embodiment, taking both of the workability in mounting the chip and the reduction in the light incidence to the side portions of the chip into consideration, the distance d between the side portions of the chip 20 and the inner walls of the wall sections 33, 32a is preferably in a range of not less than 30 μm and not more than 150 μm.

It should be noted that the distance d here represents the shortest distance, the longest distance, or the average distance in the height direction of the wall sections (the thickness direction of the chip) between the side portions of the chip 20 and the inner walls of the wall sections 33, 32a.

Further, taking both of the workability in mounting the chip and the reduction in light incidence to the side portions of the chip into consideration, the height of each of the wall sections 33, 32a is preferably not less than a half and not more than twice of the thickness of the chip 20. According to the embodiment shown in FIG. 2, the height of the wall sections 33 is larger than the thickness of the chip 20.

The inner wall 32b of the reflector 32 functions as a reflecting section for reflecting the light to the upper side of the package. The inner wall 32b of the reflector 32 is tilted so as to form an obtuse angle with the upper surfaces of the lead frames 11, 12 in order to make it easy to reflect the light upward.

In contrast, the wall sections 33, 32a disposed close to the side portions of the chip 20 function as walls not for reflecting the light from the side portions of the chip but for blocking the light incidence to the side portions of the chip.

If the inner walls of the wall sections 33, 32a are tilted so that the upper ends of the inner walls of the wall sections 33, 32a are located further from the side portions of the chip 20 than the lower ends, it becomes easy for the light to enter the side portions of the chip 20.

In contrast, if the inner walls of the wall sections 33, 32a are tilted so that the upper ends of the inner walls of the wall sections 33, 32a are located nearer to the side portions of the chip 20 than the lower ends, the workability in mounting the chip degrades.

Therefore, taking both of the workability in mounting the chip and the reduction in light incidence to the side portions of the chip into consideration, it is desirable for the inner walls of the wall sections 33, 32a to surround the side portions of the chip 20 so as to face substantially in parallel to the side portions of the chip 20.

Here, the term “parallel” is not limited to the state in which the inner walls of the wall sections 33, 32a and the side portions of the chip 20 are parallel to each other with mathematical accuracy, but includes a tilted state in which the light incidence to the side portions of the chip does not significantly increase, and it is sufficient that the inner walls of the wall sections 33, 32a and the side portions of the chip 20 are substantially parallel to each other.

In other words, besides the state in which the inner walls of the wall sections 33, 32a are accurately perpendicular to the upper surfaces of the lead frames 11, 12, there can also be included the state in which the wall sections 33, 32a are slightly tilted with respect to the upper surfaces of the lead frames 11, 12 on the grounds of the metal mold formation and so on.

The side walls of the wall sections 33 are provided with a taper for facilitating the separation from the metal mold. It should be noted that if the tilt angle of the inner walls 33a facing to the side portions of the chip is increased, it becomes easy for the return light to enter the side portions of the chip. Therefore, the tilt of the inner walls 33a of the wall sections 33 is very small.

In contrast, the tilt of the outer walls 33b of the wall sections 33 not facing to the side portions of the chip can be made to function as the light reflecting surface similar to the inner wall 32b of the reflector 32.

Therefore, as shown in FIG. 2, the angle formed between the inner walls 33a of the wall sections 33 and the upper surface of the lead frame 11 is smaller than the angle formed between the outer walls 33b of the wall sections 33 and the upper surface of the lead frame 11. The inner walls 33a each have the angle more approximate to a right angle with the upper surface of the lead frame 11 than the outer walls 33b.

The tilt angle of the inner walls 33a of the wall sections 33 is smaller than the tilt angle of the inner wall 32b of the reflector 32 functioning as the reflecting surface. The angle formed between the inner walls 33a of the wall sections 33 and the upper surfaces of the lead frames 11, 12 is smaller than the angle formed between the inner walls 32b of the reflector 32 and the upper surfaces of the lead frames 11, 12.

Further, it can be said that the inner walls of the wall sections 33, 32a and the side portions of the chip 20 are substantially parallel to each other not only in the case in which the distance between the lower ends of the side portions of the chip 20 and the wall sections 33, 32a and the distance between the upper ends of the side portions of the chip 20 and the wall sections 33, 32a are equal to each other but also in the case in which some difference exists between the distances described above.

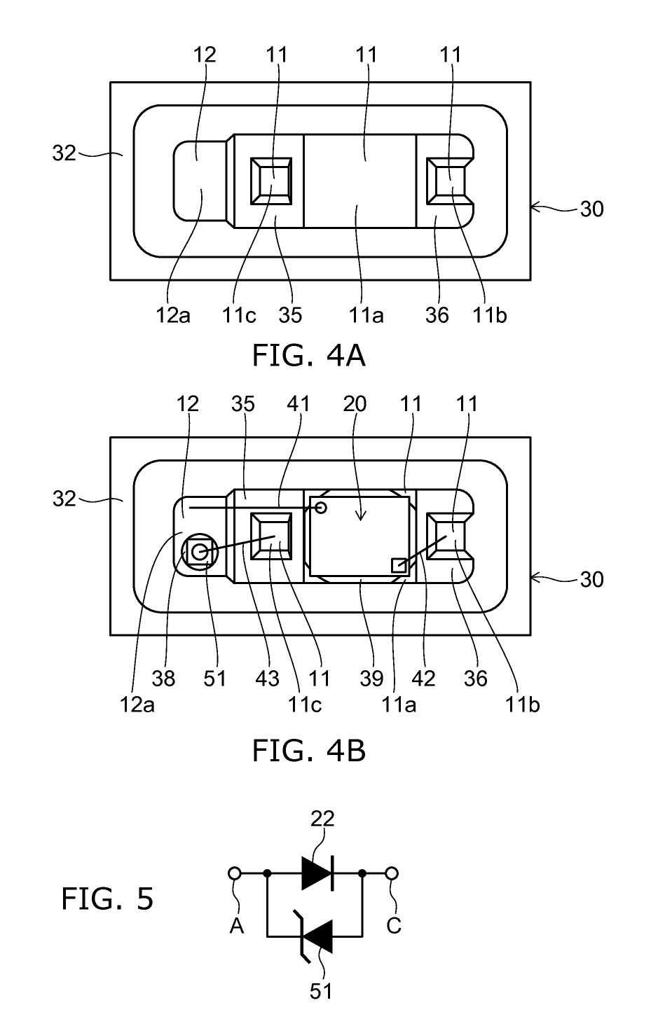

FIG. 4A is a schematic top view of a package according to another embodiment.

FIG. 4B is a schematic top view of a semiconductor light emitting device according to another embodiment.

FIGS. 4A and 4B respectively correspond to FIGS. 3A and 1A showing the embodiment described above, wherein the same elements are provided with the same symbols, and the detailed explanation will be omitted.

As described above, a silver film is formed on the surfaces of the lead frames 11, 12 using, for example, a plating method. Silver is apt to be sulfurized with long-term use. Sulfurized silver is deteriorated in reflectance.

Therefore, according to the embodiment shown in FIGS. 4A and 4B, the surfaces of the areas other than the chip mounting area and the wire bonding areas in the lead frames 11, 12 are covered with white resin 35, 36.

The upper surface of the lead frame 11 except the chip mounting area 11a and the wire bonding areas 11b, 11c, and the upper surface of the lead frame 12 except the area 12a used as both of the chip mounting area and the wire bonding area are covered with the white resin 35, 36.

By reducing the area of the silver exposed, it is possible to make the silver difficult to be sulfurized to thereby maintain the high reflectance due to the silver.

The wall sections 33 similarly to the embodiment shown in FIG. 1A are provided under the white resin 35, 36.

The white resin 35, 36 is formed integrally as a part of the resin frame 30, and has a high reflective property with respect to the radiation light of the light emitting element 22 and the phosphor particles 61.

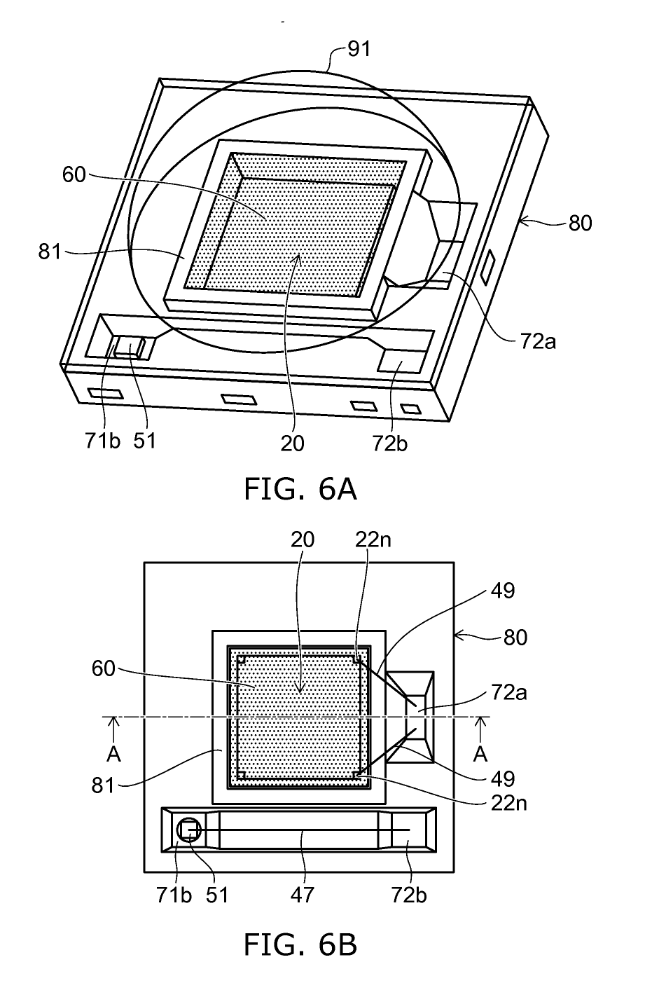

FIG. 6A is a schematic perspective view of a semiconductor light emitting device according to another embodiment.

FIG. 6B is a schematic top view of the semiconductor light emitting device according to another embodiment.

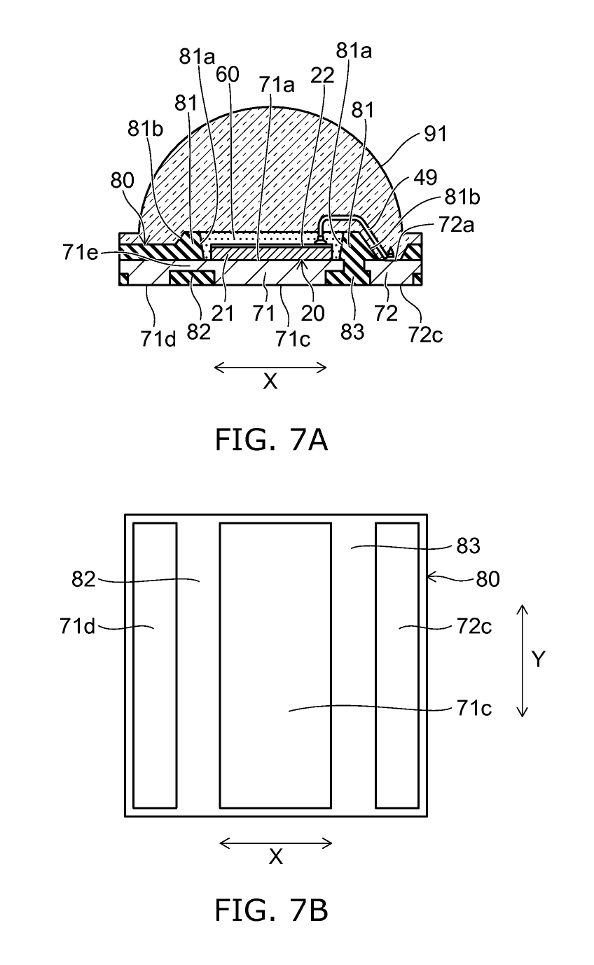

FIG. 7A is an A-A cross-sectional view in FIG. 6B.

FIG. 7B is a bottom view in FIG. 7A.

It should be noted that in FIG. 6B, a lens 91 shown in FIG. 6A is omitted. Further, in FIG. 6A, bonding wires 47, 49 shown in FIGS. 6B and 7A are omitted.

The semiconductor light emitting device shown in FIGS. 6A to 7B includes the chip 20 and a package for holding the chip 20.

The chip 20 is a light emitting diode (LED) chip, and has the light emitting element (LED element) 22 and the substrate 21 for supporting the light emitting element 22 similarly to the embodiment described above as shown in FIG. 2.

In the embodiment, for example, the p-side electrode is formed on one side (the lower side) in the thickness direction of the light emitting element 22, and the n-side pad 22n is formed on the other side (the upper side) in the thickness direction of the light emitting element 22.

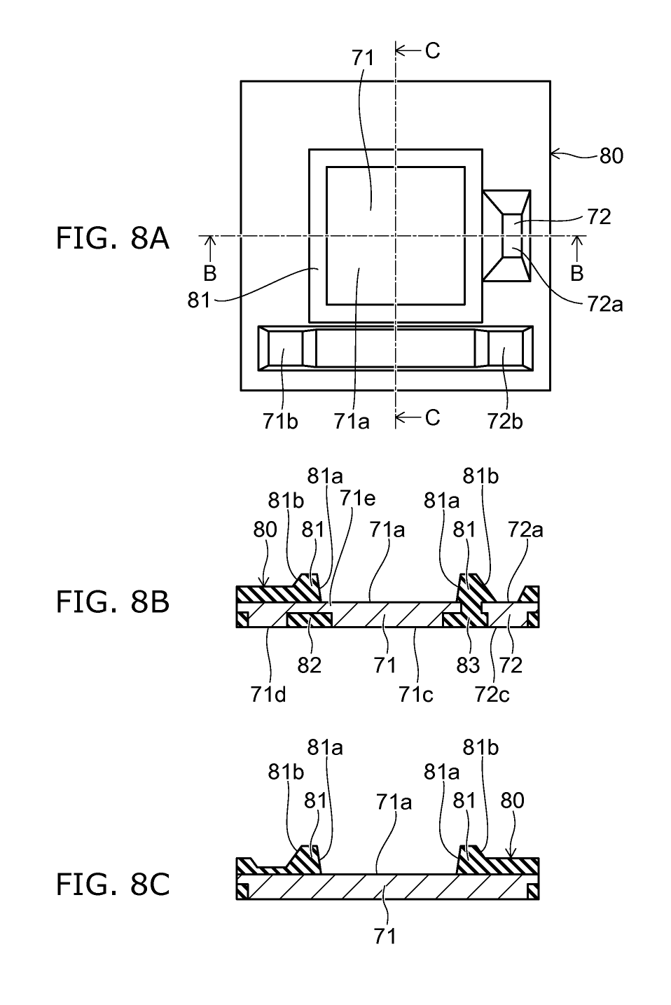

FIG. 8A is a schematic top view of the package of the semiconductor light emitting device shown in FIGS. 6A to 7B.

FIG. 8B is a B-B cross-sectional view in FIG. 8A.

FIG. 8C is a C-C cross-sectional view in FIG. 8A.

The package has a first lead frame 71, a second lead frame 72, and a resin frame 80.

The first lead frame 71 and the second lead frame 72 are each a metal molded object, and contains, for example, copper as a major ingredient. The first lead frame 71 and the second lead frame 72 are separated from each other.

The first lead frame 71 has chip mounting areas 71a, 71b. The second lead frame 72 has wire bonding areas 72a, 72b.

The resin frame 80 is formed of, for example, silicon series white resin. The resin frame 80 has a wall section 81. The wall section 81 has an inner wall 81a and an outer wall 81b located on the opposite side. The inner wall 81a faces to the chip mounting area 71a. The inner wall 81a of the wall section 81 continuously surrounds the periphery of the chip mounting area 71a of the first lead frame 71.

The chip 20 is mounted on the chip mounting area 71a. A reverse surface of the substrate 21 of the chip 20 is bonded to the upper surface of the first lead frame 71 with die bonding paste (e.g., silver paste). The lower electrode (the p-side electrode) of the light emitting element 22 is connected to the first lead frame 71 via the substrate (a silicon substrate) 21 having an electrically conductive property.

The heat generated by light emission of the light emitting element 22 is released to a mounting substrate not shown through the substrate 21 and the first lead frame 71.

The n-side pad 22n of the chip 20 is electrically connected to the second lead frame 72 via the bonding wire 49. One end of the bonding wire 49 is bonded to the n-side pad 22n, and the other end is bonded to the bonding area 72a of the second lead frame 72. The bonding wire 49 is bonded to the n-side pad 22n and the bonding area 72a of the second lead frame 72 so as to straddle over the wall section 81.

The zener diode 51 is provided on the chip mounting area 71b of the first lead frame 71. The anode electrode is formed on the lower surface of the zener diode 51, and the cathode electrode is formed on the upper surface of the zener diode 51.

The anode electrode on the lower surface of the zener diode 51 is connected to the chip mounting area 71b of the first lead frame 71 via electrically conductive paste (e.g., silver paste).

The cathode electrode on the upper surface of the zener diode 51 is electrically connected to the second lead frame 72 via the bonding wire 47. One end of the bonding wire 47 is bonded to the cathode electrode on the upper surface of the zener diode 51, and the other end is bonded to the wire bonding area 72b of the second lead frame 72.

Also in the embodiment, the LED chip 20 and the zener diode 51 are connected in parallel to each other between the anode terminal and the cathode terminal. The zener diode 51 functions as an electrostatic discharge (ESD) protection element.

As shown in FIG. 7A, the first lead frame 71 and the second lead frame 72 are separated from each other in a first direction (X-direction). The first lead frame 71 has an inner lead section 71e, and outer lead sections 71c, 71d. The inner lead section 71e has chip mounting areas 71a, 71b (FIG. 8A), and is provided so as to have a plate shape continuing in the X-direction.

The outer lead sections 71c, 71d are provided integrally with the inner lead section 71e, and project on the opposite side to the chip mounting areas 71a, 71b. The outer lead section 71c and the outer lead section 71d are separated from each other in the X-direction.

The reverse surface (a portion not covered with the resin frame 80) 72c of the second lead frame 72 functions as a cathode-side external electrode. The reverse surfaces (portions not covered with the resin frame 80) of the outer lead sections 71c, 71d of the first lead frame 71 are separated by a part 82 of the resin frame 80 into two anode-side external electrodes.

FIG. 7B is a schematic view of a reverse surface (a mounting surface) of the semiconductor light emitting device, and shows the reverse surface 72c of the second lead frame 72, and the reverse surfaces of the outer lead sections 71c, 71d of the first lead frame 71. The reverse surface 72c of the second lead frame 72 and the reverse surfaces of the outer lead sections 71c, 71d of the first lead frame 71 are each formed of, for example, a rectangular pattern.

The reverse surface 72c of the second lead frame 72 and the reverse surfaces of the outer lead sections 71c, 71d of the first lead frame 71 are equal to each other in the width in a second direction (Y-direction). In the reverse surface (the mounting surface) of the semiconductor light emitting device shown in FIG. 7B, the second direction (Y-direction) is perpendicular to the first direction (X-direction). The width in the X-direction of the reverse surface of the outer lead section 71c is larger than the width in the X-direction of the reverse surface 72c of the second lead frame 72 and the width in the X-direction of the reverse surface of the outer lead section 71d. Therefore, the area of the reverse surface of the outer lead section 71c below the chip mounting area 71a is larger than the area of the reverse surface of the outer lead section 71d and the area of the reverse surface 72c of the second lead frame 72. Therefore, it is possible to release the heat of the phosphor layer 60 and the heat of the chip 20 to the mounting substrate through the outer lead section 71c having the large area and disposed below the phosphor layer 60 and the chip 20.

The width in the X-direction of the reverse surface 72c of the second lead frame 72 and the width in the X-direction of the reverse surface of the outer lead section 71d are equal to each other. The area of the reverse surface 72c of the second lead frame 72 and the area of the reverse surface of the outer lead section 71d are equal to each other. The pitch between the reverse surface of the outer lead section 71d and the reverse surface of the outer lead section 71c and the pitch between the reverse surface of the outer lead section 71c and the reverse surface 72c of the second lead frame 72 are equal to each other.

The reverse surface of the outer lead section 71c is provided between the reverse surface of the outer lead section 71d and the reverse surface 72c of the second lead frame 72. The part 82 of the resin frame 80 is provided between the reverse surface of the outer lead section 71d and the reverse surface of the outer lead section 71c. On the part 82 of the resin frame 80, the inner lead section 71e is continuous but is not separated. A part 83 of the resin frame 80 is provided between the reverse surface of the outer lead section 71c and the reverse surface 72c of the second lead frame 72.

The reverse surface 72c of the second lead frame 72 is bonded to a cathode-side land pattern of the mounting substrate (circuit board) with solder. The reverse surfaces of the outer lead sections 71c, 71d of the first lead frame 71 are bonded to an anode-side land pattern of the mounting substrate (circuit board) with solder.

According to the layout of the mounting surface shown in FIG. 7B, the external electrodes (the reverse surface 72c of the second lead frame 72, and the reverse surfaces of the outer lead sections 71c, 71d of the first lead frame 71) are provided symmetrically about the center of the mounting surface. Therefore, the melted solder spreads so as to wet the external electrodes symmetrically without deviation about the center of the mounting surface, and thus, the semiconductor light emitting device is difficult to be tilted when being mounted, and the desired light distribution characteristic is easily obtained. Further, in the first lead frame 71 located on the anode side, the outer lead sections 71c, 71d located on the mounting surface side are separated into two parts, but are formed as an integrated single component (the first lead frame 71) via the inner lead section 71e, and therefore, do not incur increase in the number of the components.

The phosphor layer 60 is provided in the chip mounting area 71a of the first lead frame 71 surrounded by the inner wall 81a of the wall section 81. The phosphor layer 60 covers the chip 20.

On the upper surface of the package, the lens 91 is provided so as to cover the phosphor layer 60 and the wall section 81. The lens 91 is formed of transparent resin transparent with respect to the radiation light of the light emitting element 22 and the radiation light of the phosphor particles 61.

The wall section 81 is formed of white resin high in reflectance with respect to the radiation light of the light emitting element 22 and the radiation light of the phosphor particles 61.

In the embodiment, in manufacturing the package, the first lead frame 71 and the second lead frame 72 are disposed in a metal mold. The white resin is cast into the metal mold, and then heated and pressurized to be solidified. Thus, the package shown in FIGS. 8A to 8C having the first lead frame 71, the second lead frame 72, and the resin frame 80 integrally bonded to each other, is formed.

Subsequently, the chip 20 is mounted in the chip mounting area 71a, which is surrounded by the inner wall 81a of the wall section 81, via the bonding paste.

The overall size (the area) of the chip mounting area 71a is slightly larger than the external dimension (the upper surface area or the bottom surface area) of the chip 20, and thus, it is possible to mount the chip 20 in the chip mounting area 71a without interfering with the wall section 81. Therefore, gaps are formed between the inner wall 81a of the wall section 81 and the side portions of the chip 20.

The inner wall 81a of the wall section 81 continuously surrounds the periphery of the side portions of the chip 20 while facing to the side portions of the chip 20. The distances between the side portions of the chip 20 and the inner wall 81a of the wall section 81 are shorter than the thickness of the chip 20.

Since the wall section 81 is close to the side portions of the chip 20, it becomes difficult for the return light having been reflected inside the lens 91 to enter the side portions of the chip 20. As a result, it is possible to suppress the absorption loss of the light in the silicon substrate 21 to improve the light extraction efficiency to the outside of the package.

Further, also in the embodiment, taking both of the workability in mounting the chip and the reduction in the light incidence to the side portions of the chip into consideration, the distance (the shortest distance, the longest distance, or an average distance) between each of the side portions of the chip 20 and the inner wall 81a of the wall section 81 is preferably in a range of not less than 30 μm and not more than 150 μm.

The wall section 81 facing close to the side portions of the chip 20 functions as a wall not for reflecting the light from the side portions of the chip but for blocking the light incidence to the side portions of the chip.

If the inner wall 81a of the wall section 81 is tilted so that the upper end of the inner wall 81a of the wall section 81 is located further from the side portion of the chip 20 than the lower end, it becomes easy for the light to enter the side portion of the chip 20.

In contrast, if the inner wall 81a of the wall section 81 is tilted so that the upper end of the inner wall 81a of the wall section 81 is located nearer to the side portion of the chip 20 than the lower end, the workability in mounting the chip degrades.

Therefore, taking both of the workability in mounting the chip and the reduction in light incidence to the side portions of the chip into consideration, the inner wall 81a of the wall section 81 surrounds the side portions of the chip 20 so as to face in parallel to the side portions of the chip 20.

Similarly to the embodiment described above, the term “parallel” here is not limited to the state in which the inner wall 81a of the wall section 81 and the side portions of the chip 20 are parallel to each other with mathematical accuracy, but includes a tilted state in which the light incidence to the side portions of the chip does not significantly increase, and it is sufficient that the inner wall 81a of the wall section 81 and the side portions of the chip 20 are substantially parallel to each other.

In other words, besides the state in which the inner wall 81a of the wall section 81 is accurately perpendicular to the upper surface of the lead frame 71, there can also be included the state in which the inner wall 81a of the wall section 81 is slightly tilted with respect to the upper surface of the lead frame 71 on the grounds of the metal mold formation and so on.

The side wall of the wall section 81 is provided with a taper for facilitating the separation from the metal mold. It should be noted that if the tilt angle of the inner wall 81a facing to the side portions of the chip is increased, it becomes easy for the return light to enter the side portions of the chip. Therefore, the tilt of the inner wall 81a of the wall section 81 is very small. The angle formed between the inner wall 81a of the wall section 81 and the upper surfaces of the lead frames 71, 72 is smaller than the angle formed between the outer wall 81b of the wall section 81 and the upper surfaces of the lead frames 71, 72. The inner wall 81a has the angle more approximate to a right angle with the upper surfaces of the lead frames 71, 72 than the outer wall 81b.

Further, it can be said that the inner wall 81a of the wall section 81 and the side portions of the chip 20 are substantially parallel to each other not only in the case in which the distance between the lower ends of the side portions of the chip 20 and the inner wall 81a of the wall section 81 and the distance between the upper ends of the side portions of the chip 20 and the inner wall 81a of the wall section 81 are equal to each other but also in the case in which a difference exists between the distances described above.

A silver film similarly to the embodiment described above is formed on the surfaces of the lead frames 71, 72. According to the embodiment, the surfaces of the areas of the lead frames 71, 72 except the chip mounting area and the wire bonding area are covered with the resin frame 80.

The upper surface of the lead frame 71 except the chip mounting areas 71a, 71b, and the upper surface of the lead frame 72 except the wire bonding areas 72a, 72b are covered with the resin frame 80 as the white resin having high reflectance. Therefore, by reducing the area of the silver exposed, it is possible to make the silver difficult to be sulfurized to thereby maintain the high reflectance due to the silver.

Further, according to the embodiment, the height of the wall section 81 is larger than the thickness of the chip 20. The phosphor layer 60 is provided in the area on the chip 20 surrounded by the wall section 81. The phosphor layer 60 is provided so as to be limited on the chip 20 within the range of the area surrounded by the wall section 81.

The phosphor layer 60 is not provided on the resin 80 located between the lead frames 71, 72. The phosphor layer 60 fits into the surface of the lead frame 71 made of metal superior in the heat radiation property to the resin 80.

Therefore, it is possible to release the heat generated in the phosphor layer 60 to the mounting substrate with a relatively short path through the chip 20 located immediately below the phosphor layer 60 and the first lead frame 71.

Further, the lens 91 covers the area where the chip 20 and the phosphor layer 60 are provided, but does not cover the zener diode 51. Therefore, the return light having been reflected inside the lens 91 fails to enter the zener diode 51. Therefore, the deterioration of the zener diode 51 due to the return light does not occur.

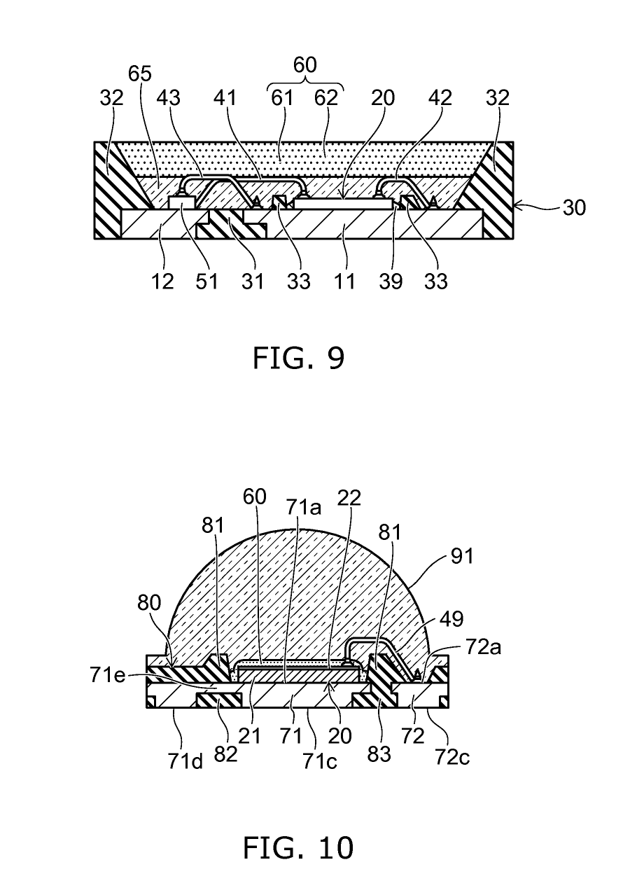

FIG. 9 is a schematic cross-sectional view showing a variation of the semiconductor light emitting device shown in FIG. 1B.

According to the semiconductor light emitting device shown in FIG. 9, the area where the chip 20, the wall sections 33, and the zener diode 51 are provided is covered with a transparent layer 65. The phosphor layer 60 is provided on the transparent layer 65.

The transparent layer 65 is formed of transparent resin transparent with respect to the radiation light of the light emitting element 22 and the radiation light of the phosphor particles 61. Alternatively, the transparent layer 65 functions as a light scattering layer. Specifically, the transparent layer 65 includes a plurality of scattering material (e.g., a titanium compound) particles for scattering the radiation light of the light emitting element 22, and a binder material (e.g., transparent resin) for integrating the plurality of scattering material particles and transmitting the radiation light of the light emitting element 22.

FIG. 10 is a schematic cross-sectional view showing a variation of the semiconductor light emitting device shown in FIG. 7A.

The resin including the phosphor particles is applied on the chip 20 so as to pot the chip 20 into the resin. On this occasion, no antisettling agent is added to the resin. The phosphor particles are higher in specific gravity than the resin component, and therefore, settle out on the surface of the chip 20 due to the own weight.

Due to the settling of the phosphor particles, the phosphor particles are eccentrically located near to the surface of the chip 20. Therefore, it is possible to cover the surface (the upper surface and the side surface) of the chip 20 with the thin phosphor layer 60. The thickness of the phosphor layer 60 is smaller than the thickness of the chip 20.

By causing the fluorescent emission in an area close to (immediately above) the chip 20, it becomes easy to release the heat of the phosphor particles to the lead frame 71 through the chip 20. Therefore, the rise in temperature in the case in which the phosphor particles emit light can be suppressed, and thus, the deterioration of the characteristics and the life due to the heat can be suppressed.

Further, it becomes easy to form the phosphor layer 60 with an even thickness on the surface of the chip 20, and it becomes possible to suppress color breakup due to uneven thickness of the phosphor layer 60.

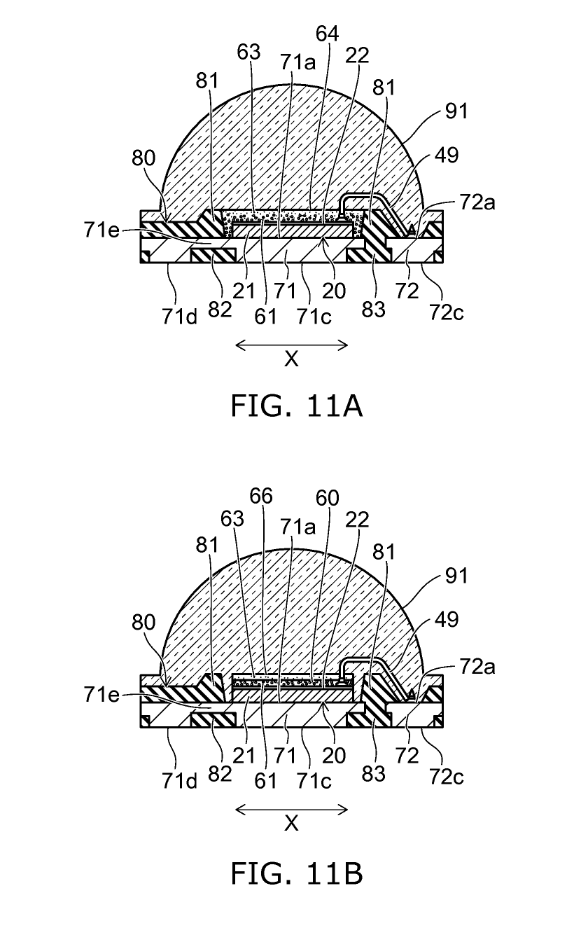

FIG. 11A is a schematic cross-sectional view of a semiconductor light emitting device according to another embodiment similar to FIG. 7A. The elements substantially the same as those shown in FIG. 7A are denoted with the same reference symbols, and the detailed explanation thereof will be omitted.

A phosphor layer 64 is provided in the area surrounded by the wall section 81. The phosphor layer 64 has resin (binder), the plurality of phosphor particles 61 dispersed in the resin, and a plurality of light scattering material particles 63 dispersed in the resin. The resin is, for example, silicone resin.

The resin including the phosphor particles 61 and the light scattering material particles 63 is applied on the chip 20 so as to pot the chip 20 into the resin. On this occasion, no antisettling agent is added to the resin. The phosphor particles 61 are higher in specific gravity than the resin component and the light scattering material particles 63, and therefore, settle out on the surface of the chip 20 due to the own weight. Due to the settling of the phosphor particles 61, the phosphor particles 61 are eccentrically located near to the surface of the chip 20. On the chip 20 side, the concentration (density) of the phosphor particles 61 is higher than the concentration (density) of the light scattering material particles 63. Therefore, it becomes easy to release the heat of the phosphor particles 61 to the lead frame 71 through the chip 20.

The light scattering material particles 63 are, for example, particles of silicon oxide. The emission light (e.g., blue light) of the light emitting element 22 is scattered by the light scattering material particles 63, and is then dispersed in a horizontal direction. Therefore, it is possible to suppress the color breakup in which the light emitted in the horizontal direction has a color tone (e.g., a yellowish color tone) of the emission light of the phosphor particles 61 compared to the light emitted in the upright direction. It becomes possible to suppress the chromaticity unevenness depending on the angle at which the semiconductor light emitting device is viewed to thereby achieve homogenous emission of the light with a desired color.

If the light scattering material particles are dispersed in the lens 91, the lens effect is damaged due to diffusion of the light. This can cause the deterioration of the light extraction efficiency and the shift of the light emission point from the center of a hemispherical lens. The shift of the light emission point from the center of the lens makes it difficult to perform matching such as alignment of the optical axis with a secondary lens.

In contrast, according to the embodiment, the light scattering material particles are not dispersed in the lens 91, but are dispersed in the resin containing the phosphor particles 61. Therefore, the desired lens effect due to the lens 91 can be exerted.

Further, it is also possible to attach a resin sheet (a phosphor resin layer) 60, which has the phosphor particles 61 dispersed, to the surface of the chip 20, and further attach a resin sheet (a light scattering resin layer) 66, which has the light scattering material particles 63 dispersed, to the surface of the resin sheet 60 as shown in FIG. 11B.

Also in this case, since the phosphor particles 61 are eccentrically located near to the surface of the chip 20, it becomes easy to release the heat of the phosphor particles 61 to the lead frame 71 through the chip 20. Further, since the emission light (e.g., blue light) of the light emitting element 22 is scattered by the light scattering material particles 63, and is thus diffused in the horizontal direction, it is possible to suppress the color breakup in which the light emitted in the horizontal direction has a color tone (e.g., a yellowish color tone) of the emission light of the phosphor particles 61 compared to the light emitted in the upright direction. Further, since the lens 91 does not include the light scattering material particles, the desired lens effect due to the lens 91 can be exerted.

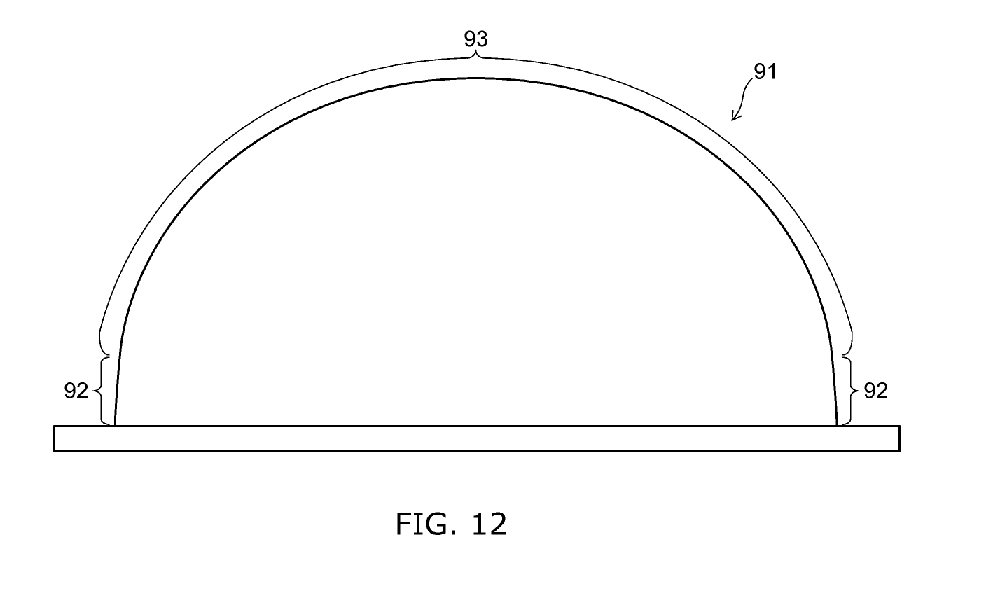

FIG. 12 is a schematic side view of the lens 91. The lens 91 shown in FIG. 12 can be applied to the semiconductor light emitting devices shown in FIGS. 7A, 10, 11A, and 11B described above.

The lens 91 includes a convex surface 93 as a part of, for example, a spherical surface, and a side surface 92 different in curvature (a curvature radius) from the convex surface 93. The contour line of the lens 91 is a part of an ellipse, or is approximated by the part of the ellipse. Here, the “ellipse” includes not only a mathematical ellipse, but also a shape formed of lines different in curvature from each other continuously connected to each other.

The center of the convex surface 93 is located at the highest point of the lens 91. The height here is a height based on the chip 20 side, and represents the height along the direction of vertically penetrating the chip 20. In the side view shown in FIG. 12, the side surface 92 is continuous with the lower end of the convex surface 93 with the longest creeping distance from the center of the convex surface 93. The height of the side surface 92 is smaller than the height of the convex surface 93.

The curvature of the side surface 92 is smaller than the curvature of the convex surface 93. The convex surface 93 and the side surface 92 are continuous with each other via no inflection point. In other words, the convex surface 93 and the side surface 92 are the same in sign of curvature, and the side surface 92 is not convex toward the inside of the lens 91.

The lens 91 having such a shape suppresses the color breakup in which the light emitted in the horizontal direction has a color tone (e.g., a yellowish color tone) of the emission light of the phosphor particles compared to the light emitted in the upright direction.

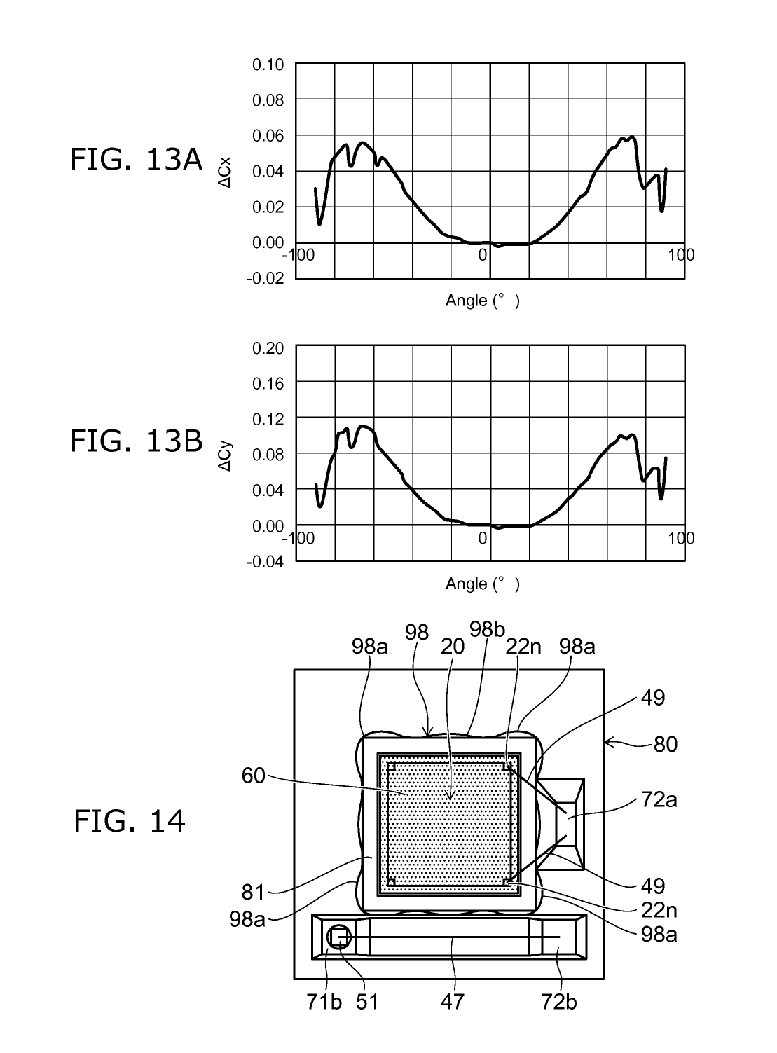

FIGS. 13A and 13B show the result obtained by a simulation of ΔCx and ΔCy of the semiconductor light emitting device according to the embodiment having the lens 91 shown in FIG. 12.

The symbols Cx and Cy represent the coordinates of a CIE chromaticity diagram. The horizontal axes in FIGS. 13A and 13B each represent a light emission direction (angle) based on the upright direction (0°) of the semiconductor light emitting device.

The vertical axis in FIG. 13A represents a relative variation ΔCx of Cx with respect to the value of Cx at 0°.

The vertical axis in FIG. 13B represents a relative variation ΔCy of Cy with respect to the value of Cy at 0°.

According to the result shown in FIG. 13A, it is understood that ΔCx falls within 0.06, which is the ANSI (American National Standard Institute) standard.

According to the result shown in FIG. 13B, it is understood that ΔCy falls within 0.12, which is the ANSI standard.

Therefore, the lens 91 having the shape shown in FIG. 12 suppresses the color breakup.

FIG. 14 is a top view obtained by showing a lens 98 so as to overlap the top view shown in FIG. 6B described above.

The lens 98 is formed to have a shape having one first part 98b and a plurality of (e.g., four) second parts 98a combined with each other in the top view shown in FIG. 14. If the second parts 98a are excluded and the first part 98b is made to be a continuous shape, a circular shape is obtained.

The first part 98b covers the light emitting area having a quadrangular shape including the chip 20 and the phosphor layer 60 except the four corners of the light emitting area. The four second parts 98a respectively cover the four corners of the light emitting area having the quadrangular shape. The second parts 98a projects on the outer circumferential side of the first part 98b so as to respectively cover the corners of the light emitting area.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor light emitting device comprising:
a lead frame;
a chip mounted on the lead frame, the chip including a substrate and a light emitting element provided on the substrate;
a wall section including an inner wall facing to a side portion of the chip, and an outer wall on an opposite side to the inner wall; and
a phosphor layer provided on at least the chip,
a distance between the side portion of the chip and the inner wall of the wall section being smaller than a thickness of the chip, and
an angle between an upper surface of the lead frame and the inner wall being smaller than an angle between the upper surface of the lead frame and the outer wall.

2. A semiconductor light emitting device comprising:
a lead frame;
a chip mounted on the lead frame, the chip including a substrate and a light emitting element provided on the substrate;
a wall section including an inner wall facing to a side portion of the chip, and an outer wall on an opposite side to the inner wall; and
a phosphor layer provided on the chip within a range of an inside area of the inner wall of the wall section, the phosphor layer being thinner than the chip,
a distance between the side portion of the chip and the inner wall of the wall section being smaller than a thickness of the chip.

3. The device according to claim 1, wherein the inner wall of the wall section is facing in parallel to the side portion of the chip.

4. The device according to claim 1, wherein the distance between the side portion of the chip and the inner wall of the wall section is not less than 30 μm and not more than 150 μm.

5. The device according to claim 1, wherein the wall section includes resin.

6. The device according to claim 1, wherein the phosphor layer is provided on the chip within a range of an inside area of the inner wall of the wall section.

7. The device according to claim 1, wherein the substrate is a silicon substrate.

8. The device according to claim 1, further comprising:
a wire straddling the wall section, and connecting an upper surface of the chip and the lead frame.

9. The device according to claim 1, wherein
the lead frame includes a first area and a second area, the chip mounted on the first area, the wire bonded to the second area, and
a surface of an area other than the first area and the second area in the lead frame is covered with a resin.

10. The device according to claim 1, further comprising:
a zener diode mounted on the lead frame, and electrically connected in parallel to the light emitting element.

11. The device according to claim 10, further comprising:
a lens covering an area in which the chip and the phosphor layer are provided, and not covering the zener diode.

12. The device according to claim 1, wherein
the phosphor layer includes
a resin,
a plurality of phosphor particles dispersed in the resin, and
a plurality of light scattering material particles dispersed in the resin.

13. The device according to claim 12, wherein a concentration of the phosphor particles is higher than a concentration of the light scattering material particles on a side close to the chip.

14. The device according to claim 1, further comprising:
a resin layer provided on the phosphor layer, and including a plurality of light scattering material particles dispersed.

15. The device according to claim 12, further comprising:
a lens covering an area in which the chip and the phosphor layer are provided.

16. The device according to claim 11, wherein
the lens includes
a convex surface, and
a side surface being continuous downward with the convex surface, and being smaller in curvature than the convex surface.

17. The device according to claim 16, wherein the convex surface and the side surface are continuous with each other without intervention of an inflection point.

18. The device according to claim 15, wherein
the lens includes
a convex surface, and
a side surface being continuous downward with the convex surface, and being smaller in curvature than the convex surface.

19. The device according to claim 18, wherein the convex surface and the side surface are continuous with each other without intervention of an inflection point.

20. A lead frame comprising:
a first lead frame including:
an inner lead section continuous in a first direction; and
a plurality of outer lead sections integrally provided to the inner lead section, and separated in the first direction from each other; and
a second lead frame separately provided in the first direction with respect to the first lead frame.
